(19) United States
(12) Patent Application Publication
(10) Pub. No.: US 2025/0338397 A1
(43) Pub. Date: Oct. 30, 2025

(54) TRANSPARENT-FREEFORM WIRING WITH AUXETIC STRUCTURE AND METHOD FOR MANUFACTURING THE SAME

(71) Applicants: GWANGJU INSTITUTE OF SCIENCE AND TECHNOLOGY, Gwangju (KR); SEOUL NATIONAL UNIVERSITY R&DB FOUNDATION, Seoul (KR)

(72) Inventors: Young Chang JOO, Seoul (KR); Han Wool YEON, Gwangju (KR); Seon Gi LEE, Seoul (KR); Sung Jae CHOI, Bucheon-si (KR)

(21) Appl. No.: 19/094,801

(22) Filed: Mar. 28, 2025

(30) Foreign Application Priority Data
Apr. 30, 2024 (KR) 10-2024-0057920
Dec. 3, 2024 (KR) 10-2024-0177165

(51) Int. Cl. H05K 1/02

(52) U.S. Cl. CPC H05K 1/0283

(57) ABSTRACT

The present inventive concept relates to a transparent-freeform wiring with an auxetic structure and a method for manufacturing the same. Strain of the transparent-freeform wiring may be improved by repeatedly connecting the auxetic structure, which consists of rotating tiles, hinges, and coupling rotating tiles, and excellent electrical conductivity may be achieved by depositing a metal thin film inside the transparent-freeform wiring.

### CROSS-REFERENCE TO RELATED APPLICATION

This application claims priority to and the benefit of Korean Patent Application No. 10-2024-0057920, filed on Apr. 30, 2024 and No. 10-2024-0177165, filed on Dec. 3, 2024, the disclosure of which is incorporated herein by reference in its entirety.

### BACKGROUND

### 1. Field

The present inventive concept relates to a transparent-freeform wiring with an auxetic structure and a method for manufacturing the same. More particularly, the present inventive concept relates to a transparent-freeform wiring that includes a composite transparent conductive thin film formed with an auxetic structure, which exhibits high strain and electrical conductivity, and a method for manufacturing the same.

### 2. Discussion of Related Art

Transparent freeform wiring technology refers to a technology for forming electronic circuits using transparent materials that have conductivity and enables wiring in curved or irregular structures, and thus is a material that is attracting attention in various industrial fields where transparent displays or flexible displays can be used, such as solar cells, smart wearable devices, skin-attachable devices, smart farms, and next-generation medical devices.

Transparent freeform wiring technology must maintain high electrical conductivity without mechanical slack on the skin or various objects, based on high strain and low elastic modulus.

Accordingly, research is being conducted on new materials, such as metal fiber fabrication technology, carbon nanotube technology, electronic gel technology, and liquid metal technology that simultaneously satisfy high strain and high conductivity. However, due to the low level of technological maturity, these materials are not highly compatible with conventional semiconductor processes and suffer from issues such as low reliability and productivity.

Accordingly, there is a need to conduct research on a transparent-freeform wiring, which is capable of withstanding high tensile strain while maintaining high electrical conductivity, based on materials with high technological maturity.

### SUMMARY

A first objective of the present disclosure is to provide a transparent-freeform wiring with an auxetic structure.

A second objective of the present inventive concept is to provide a method for manufacturing the transparent-freeform wiring with an auxetic structure to achieve the first objective.

To achieve the above-described first objective, the present inventive concept provides a transparent-freeform wiring with an auxetic structure. The transparent-freeform wiring includes a stretchable substrate, and a composite transparent conductive thin film with an auxetic structure formed on the stretchable substrate, wherein the composite transparent conductive thin film has a sandwich structure in which a metal thin film is formed between one or more transparent conductive thin films.

To achieve the above-described second objective, the present inventive concept provides a method for manufacturing a transparent-freeform wiring with an auxetic structure. The transparent-freeform wiring with an auxetic structure is manufactured by forming a sacrificial layer on a substrate, forming a composite transparent conductive thin film by depositing one or more transparent conductive thin films and a metal thin film onto the sacrificial layer, removing the sacrificial layer, and transferring the composite transparent conductive thin film onto a stretchable substrate.

The composite transparent conductive thin film may have an auxetic structure, and the auxetic structure may be patterned onto each transparent conductive thin film or patterned after forming the composite transparent conductive thin film.

### BRIEF DESCRIPTION OF THE DRAWINGS

The above and other objects, features, and advantages of the present inventive concept will become more apparent to those of ordinary skill in the art by describing exemplary embodiments thereof in detail with reference to the accompanying drawings, in which:

FIG. 1 is a three-dimensional view illustrating a structure of a transparent-freeform wiring according to an exemplary embodiment of the present inventive concept;

FIGS. 2A and 2B are views illustrating an auxetic structure according to the exemplary embodiment of the present inventive concept;

FIG. 3 is a view illustrating strain according to a rotating angle of the exemplary embodiment of the present inventive concept;

FIG. 4 is a graph illustrating the strain according to the rotating angle of the exemplary embodiment of the present inventive concept; and

FIGS. 5A and 5B are a set of graphs showing stress-strain test results according to the exemplary embodiment of the present inventive concept.

### DETAILED DESCRIPTION OF EXEMPLARY EMBODIMENTS

While the present inventive concept is susceptible to various modifications and alternative forms, specific embodiments thereof are shown by way of example in the drawings and will herein be described in detail in the text. It should be understood, however, that there is no intent to limit the present inventive concept to the particular forms disclosed, but on the contrary, the present inventive concept is to cover all modifications, equivalents, and alternatives falling within the spirit and scope of the present inventive concept.

Unless otherwise defined, all terms used herein including technical or scientific terms have the same meanings as those generally understood by one of ordinary skill in the art. It should be further understood that terms, such as those defined in commonly used dictionaries, should be interpreted as having a meaning that is consistent with their meaning in the context of the relevant art and are not to be interpreted in an idealized or overly formal sense unless expressly so defined herein.

In the specification, when it is stated that a portion of a layer, a film, a plate, or the like is present “on” or “over” another portion, the portion of the layer, film, plate, or the like may be directly formed on another portion of another layer, film, plate, or the like, or may have still another portion interposed therebetween.

In the specification, “transparent-freeform wiring” may be used interchangeably with “transparent wiring,” but they have the same meaning.

Hereinafter, with reference to the accompanying drawings, various embodiments of the present inventive concept will be described in more detail.

### EXAMPLES

The present inventive concept provides a transparent-freeform wiring with an auxetic structure. FIG. 1 is a three-dimensional 1 view illustrating a structure of the transparent-freeform wiring with an auxetic structure.

Referring to FIG. 1, the transparent-freeform wiring with an auxetic structure has a structure that includes a stretchable substrate 100 and a composite transparent conductive thin film 200 formed on the stretchable substrate 100.

The composite transparent conductive thin film 200 may have a sandwich structure in which a metal thin film is interposed between one or more transparent conductive thin films. More preferably, the composite transparent conductive thin film 200 may have a structure including a first transparent conductive thin film 200a, a metal thin film 200b formed on the first transparent conductive thin film 200a, and a second transparent conductive thin film 200c formed on the metal thin film 200b.

The stretchable substrate 100 is preferably made of polydimethylsiloxane (PDMS), but the present inventive concept is not limited thereto, and any material with stretchability and high transparency is sufficient for the stretchable substrate 100.

The transparent conductive thin film is preferably made of indium tin oxide (ITO), but the present inventive concept is not limited thereto, and any transparent conductor that can be formed at a temperature less than 400° C. is sufficient for the transparent conductive thin film.

The composite transparent conductive thin film 200 may have a structure in which a metal thin film is deposited between transparent conductive thin films in which an auxetic structure is formed, or may be in a state in which the auxetic structure is formed after the manufacture of the composite transparent conductive thin film. In addition, the auxetic structure may be patterned through an etching or lift-off process. The auxetic structure is based on auxetic technology, which improves deformability by substituting tensile deformation of an object with rotational and bending deformation through cuts.

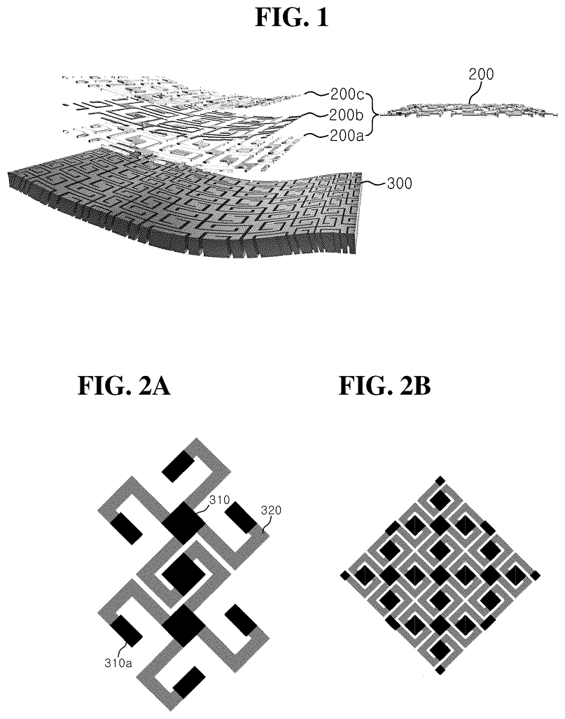

FIG. 2 is a view illustrating the auxetic structure.

Referring to FIG. 2A, which illustrates the auxetic structure, the auxetic structure includes a rotating tile 310 at its center of rotation, and four hinges 320 are connected to the rotating tile 310 in an “L” shape. Opposite sides of the hinges 320 connected to the rotating tile 310 are each configured as coupling rotating tiles 310a. When the coupling rotating tile 310a is connected to a coupling rotating tile 310a of another auxetic structure to extend into a structure shown in FIG. 2B, these coupling rotating tiles 310a become another rotating tile 310 while forming another center of rotation.

The “L” shape of the hinge 320 allows a bent portion to unfold when the transparent-freeform wiring is subjected to stress, thereby enabling high strain.

The hinge 320 has an extended portion at a terminal end of its “L” shape, and thus, the hinge 320 may have a “C”-shape.

The rotating tile 310, the hinge 320, and the coupling rotating tile 310a are each a portion of the composite transparent conductive thin film 200, which is formed by patterning the transparent conductive thin film into an auxetic structure, and thus are made of the same material.

The present inventive concept provides a method for manufacturing the transparent-freeform wiring.

The transparent-freeform wiring with an auxetic structure is manufactured through operations including a first operation of forming a sacrificial layer on a substrate, a second operation of forming a composite transparent conductive thin film by depositing one or more transparent conductive thin films and a metal thin film on the sacrificial layer formed in the first operation, a third operation of removing the sacrificial layer below the composite transparent conductive thin film, which is formed in the second operation, through an electrochemical reaction to separate the composite transparent conductive thin film from the substrate, and a fourth operation of transferring the composite transparent conductive thin film, which is separated in the third operation, onto a stretchable substrate, and the composite transparent conductive thin film has an auxetic structure.

In the first operation, a sacrificial layer is formed on a substrate. The first operation may be the same as a wafer process in a conventional semiconductor manufacturing process.

In the second operation, one or more transparent conductive thin films and a metal thin film are deposited on the sacrificial layer formed in the first operation to form a composite transparent conductive thin film.

The composite transparent conductive thin film may have a sandwich structure in which the metal thin film is formed between the transparent conductive thin films by sequentially depositing a first transparent conductive thin film, a metal thin film, and a second transparent conductive thin film.

The composite transparent conductive thin film in the second operation may be manufactured through operations of forming the first transparent conductive thin film on the sacrificial layer, forming the metal thin film on the first transparent conductive thin film, forming the second transparent conductive thin film on the metal thin film to form the composite transparent conductive thin film, and patterning an auxetic structure on the composite transparent conductive thin film through an etching or lift-off process.

The composite transparent conductive thin film in the second operation may be manufactured through operations of forming the first transparent conductive thin film on the sacrificial layer, forming an auxetic structure on the first transparent conductive thin film, forming the metal thin film on the first transparent conductive thin film, forming the second transparent conductive thin film on the metal thin film, and forming an auxetic structure on the second transparent conductive thin film, and the auxetic structure may be patterned through an etching or lift-off process.

The transparent conductive thin film is preferably made of indium tin oxide (ITO), but the present inventive concept is not limited thereto, and any transparent conductor that can be formed at a temperature less than 400° C. is sufficient for the transparent conductive thin film.

The transparent conductive thin film may have an auxetic structure and be patterned through an etching or lift-off process, but the present inventive concept is not limited thereto. The unit of the auxetic structure includes a rotating tile at the center of rotation, with four hinges each connected to the rotating tile in an “L” shape. Opposite sides of the hinges connected to the rotating tile are configured as coupling rotating tiles, and when the coupling rotating tile is connected to a coupling rotating tile of another auxetic structure to extend, these coupling rotating tiles become another rotating tile while forming another center of rotation.

The “L” shape of the hinge allows a bent portion to unfold when the transparent-freeform wiring is subjected to stress, thereby enabling high strain.

The hinge has an extended portion at a terminal end of its “L” shape, and thus, the hinge may have a “C”-shape.

The rotating tile, the hinges, and the coupling rotating tiles are patterned from the transparent conductive thin film into an auxetic structure and thus are made of the same material.

The transparent conductive thin film can be deposited to a thickness of 0.01 μm to 1 μm to achieve high bending flexibility.

The metal thin film may be made of copper, but is not limited thereto.

By inserting the metal thin film into the composite transparent conductive thin film, high electrical conductivity and deformation resistance can be achieved when forming transparent-freeform wiring, thereby improving durability and speed compared to conventional wiring.

In the third operation, the sacrificial layer below the composite transparent conductive thin film manufactured in the second operation is removed through an electrochemical reaction to separate the composite transparent conductive thin film from the substrate.

In the fourth operation, the composite transparent conductive thin film separated in the third operation is transferred onto a stretchable substrate to manufacture the transparent-freeform wiring. After aligning the composite transparent conductive thin film onto the stretchable substrate, curing and mold removal may be performed to finally manufacture the transparent-freeform wiring with an auxetic structure.

The stretchable substrate may be PDMS, but the present inventive concept is not limited thereto, and any material with stretchability is sufficient for the stretchable substrate.

The stretchable substrate may be formed by forming a patterned mold, followed by spin-coating a stretchable substrate material.

### Manufacturing Example

A sacrificial layer was formed by depositing aluminum (Al)/titanium (Ti) with thicknesses of 200/40 nm on a silicon (Si) wafer. On the sacrificial layer, a composite transparent conductive thin film of ITO/copper (Cu)/ITO with thicknesses of 100 nm/12 nm/100 nm was deposited by radio frequency (RF) sputtering under conditions of 100° C. and 4.5 mTorr. The composite transparent conductive thin film was formed into an auxetic structure through a liftoff process. Subsequently, the wafer was diced and attached to thermal release tape, and the sacrificial layer was then removed through an electrochemical release process to manufacture the composite transparent conductive thin film with an auxetic structure.

After etching the Si wafer to produce a mold for patterning PDMS, PDMS was spin-coated onto the mold, and the manufactured composite transparent conductive thin film with an auxetic structure was aligned on the PDMS. Subsequently, the PDMS was cured at 80° C. on a hotplate for 3 hours, and then the release tape and the PDMS, on which the composite transparent conductive thin film with an auxetic structure is aligned, were peeled off from the mold. The peeled PDMS was heated on a hotplate at a temperature greater than or equal to 120° C. for 5 minutes to remove an adhesive force of the release tape, and then immersed in acetone to separate the composite transparent conductive thin film with an auxetic structure, which was transferred onto the PDMS, from the release tape, thereby manufacturing the transparent-freeform wiring with an auxetic structure.

### Comparative Example

A composite transparent conductive thin film was manufactured under the same conditions as in the manufacturing example, except for being patterned into a kirigami structure.

### Measurement Example

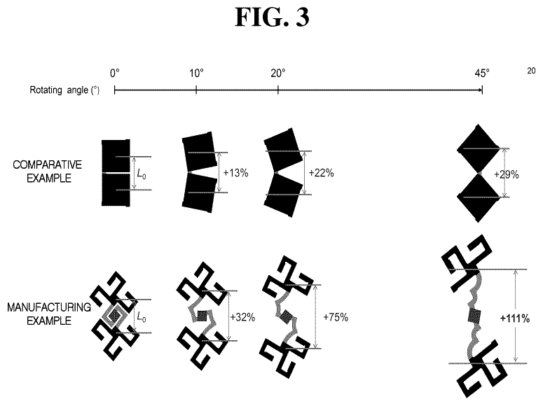

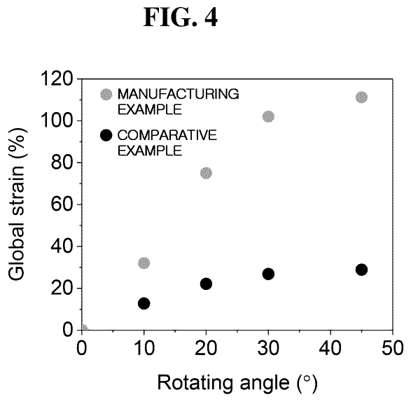

FIG. 3 is a view illustrating strain resulting from a rotating angle for the manufacturing example and the comparative example, and FIG. 4 illustrates a graph of measured values from FIG. 3. The transparent-freeform wiring of each of the manufacturing example and the comparative example was transferred onto a tattoo sticker, and experiments were conducted thereon.

Referring to FIGS. 3 and 4, when comparing the manufacturing example and the comparative example, the manufacturing example exhibited a higher strain than the comparative example for the same rotating angle. In addition, when the rotating angle is 45°, the comparative example showed a 29% increase in length compared to when the rotating angle was 0°, whereas the manufacturing example exhibited a 111% increase in length without any segmentation.

Accordingly, it can be seen from FIGS. 3 and 4 that the manufacturing example exhibits higher strain and flexibility.

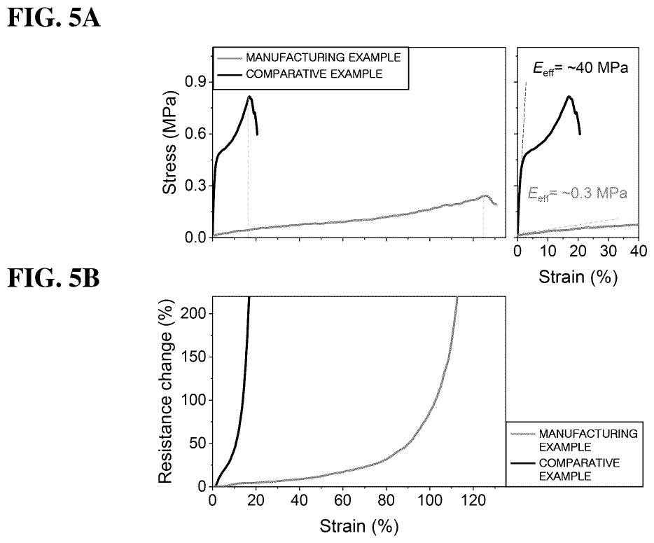

FIG. 5 is a set of graphs showing stress-strain test results for the manufacturing example and the comparative example.

Referring to FIG. 5, the transparent-freeform wiring in the manufacturing example deformed more easily under lower applied force compared to that in the comparative example, and also exhibited a higher strain. On the other hand, the transparent-freeform wiring in the manufacturing example had an effective elastic modulus less than or equal to 0.3 MPa, which is lower than that of the comparative example, which is below 40 MPa, and also exhibited superior deformation resistance compared to the comparative example.

Thus, as shown in FIG. 5, the manufacturing example with an auxetic structure exhibits superior durability compared to the related art due to its high deformation resistance, high strain, and low elastic modulus.

Thus, according to the present inventive concept, by forming an auxetic structure in the transparent conductive thin film of the transparent-freeform wiring, high strain, excellent stretchability, and high transmittance may be simultaneously achieved. In addition, the auxetic structure may increase the number of rotating tiles within the same area compared to the related art and thus exhibit superior mechanical properties, thereby overcoming inherent mechanical brittleness of traditional transparent conductive thin films.

The transparent-freeform wiring may minimize the decrease in transparency by depositing the thin metal film between the transparent conductive thin films and improve electrical conductivity by more than ten times compared to the related art.

Accordingly, the transparent-freeform wiring of the present inventive concept has excellent properties such as high strain, transparency, and electrical conductivity, and thus is applicable to various industrial fields, such as next-generation display industries, solar cell industries, wearable device industries, and medical device industries. In addition, the transparent-freeform wiring of the present inventive concept, as a material with excellent compatibility with existing semiconductor processes, may achieve high integration density, productivity, and reliability.

What is claimed is:

1. A transparent-freeform wiring with an auxetic structure, the transparent-freeform wiring comprising:
a stretchable substrate; and
a composite transparent conductive thin film with an auxetic structure formed on the stretchable substrate,
wherein the composite transparent conductive thin film has a sandwich structure in which a metal thin film is formed between one or more transparent conductive thin films.

2. The transparent-freeform wiring of claim 1, wherein
the auxetic structure includes one rotating tile at a center portion thereof, two or more hinges connected to the rotating tile, and coupling rotating tiles respectively formed at ends of the hinges, and
the auxetic structure is repeatedly connected.

3. The transparent-freeform wiring of claim 2, wherein the rotating tile, the hinges, and the coupling rotating tiles are made of the same material.

4. The transparent-freeform wiring of claim 2, wherein the coupling rotating tiles serve as connection parts of the auxetic structure, and when two or more coupling rotating tiles are coupled, the two or more coupling rotating tiles function as the rotating tile.

5. The transparent-freeform wiring of claim 2, wherein
each of the hinges has an “L” shape, and
when a force is applied to the auxetic structure, bent portions of the hinges unfold to change a shape of the transparent-freeform wiring.

6. The transparent-freeform wiring of claim 5, wherein each of the hinges has an extended portion at a terminal end of the “L” shape, and each of the hinges has a “C” shape.

7. The transparent-freeform wiring of claim 1, wherein the transparent conductive thin film is indium tin oxide (ITO).

8. A method for manufacturing a transparent-freeform wiring with an auxetic structure, comprising:
forming a sacrificial layer on a substrate;
forming a composite transparent conductive thin film by depositing one or more transparent conductive thin films and a metal thin film on the sacrificial layer;
removing the sacrificial layer through an electrochemical reaction to separate the composite transparent conductive thin film from the substrate; and
transferring the composite transparent conductive thin film onto a stretchable substrate,
wherein the composite transparent conductive thin film is formed into the auxetic structure.

9. The method of claim 8, wherein the forming of the composite transparent conductive thin film by depositing one or more transparent conductive thin films and the metal thin film on the sacrificial layer includes:
forming a first transparent conductive thin film on the sacrificial layer;
forming a metal thin film on the first transparent conductive thin film;
forming a second transparent conductive thin film on the metal thin film to form the composite transparent conductive thin film; and
forming the auxetic structure on the composite transparent conductive thin film.

10. The method of claim 8, wherein the forming of the composite transparent conductive thin film by depositing one or more transparent conductive thin films and the metal thin film on the sacrificial layer includes:
forming a first transparent conductive thin film on the sacrificial layer;
forming the auxetic structure on the first transparent conductive thin film;
forming a metal thin film on the first transparent conductive thin film;
forming a second transparent conductive thin film on the metal thin film; and
forming the auxetic structure on the second transparent conductive thin film.

11. The method of claim 8, wherein
the auxetic structure includes one rotating tile at a center portion thereof, two or more hinges connected to the rotating tile, and coupling rotating tiles respectively formed at ends of the hinges, and
the auxetic structure is repeatedly connected.

12. The method of claim 11, wherein the rotating tile, the hinges, and the coupling rotating tiles are made of the same material.

13. The method of claim 11, wherein the coupling rotating tiles serve as connection parts of the auxetic structure, and when two or more coupling rotating tiles are coupled, the two or more coupling rotating tiles function as the rotating tile.

14. The method of claim 11, wherein
each of the hinges has an ‘L’ shape, and
when a force is applied to the auxetic structure, bent portions of the hinges unfold to change a shape of the transparent-freeform wiring.

15. The method of claim 14, wherein each of the hinges has an extended portion at a terminal end of the “L” shape, and each of the hinges has a “C” shape.

16. The method of claim 8, wherein the transparent conductive thin film is indium tin oxide (ITO).

17. The method of claim 8, wherein the transparent conductive thin film is deposited to a thickness ranging from 0.01 μm to 1 μm.
